(19) United States
(12) Patent Application Publication
(10) Pub. No.: US 2022/0261518 A1
(43) Pub. Date: Aug. 18, 2022

(54) METHOD OF AND SYSTEM FOR OPERATING STORAGE AREA NETWORK SIMULATOR

(71) Applicant: YADRO INTERNATIONAL LTD., Nicosia (CY)

(72) Inventors: Artem IKOEV, Moscow (RU); Ivan TCHOUB, St.Petersburg (RU); Kenenbek ARZYMATOV, Moscow (RU); Andrey USTYUZHANIN, Moscow (RU); Vladislav BELAVIN, Moscow (RU); Andrey SAPRONOV, Dubna (RU); Maksim KARPOV, Town Snegiri (RU); Leonid GREMYACHIKH, Pushkin city district (RU)

(21) Appl. No.: 17/176,122

(22) Filed: Feb. 15, 2021

(51) Int. Cl. G06F 30/27

(52) U.S. Cl. CPC G06F 30/27

(57) ABSTRACT

There is disclosed a method and system for operating a storage area network (SAN) simulator. The method comprises generating training data representative of a SAN system. The method also comprises generating a SAN simulator corresponding to the SAN system, where the SAN simulator outputs a predicted metric of at least one component of the SAN system.

The method then comprises using the training data to train a machine learning algorithm (MLA) to determine adjustments for parameters of the SAN simulator.

### FIELD

The present technology relates to simulating a storage area network (SAN) and, more specifically, to a method of and a system for operating a SAN simulator.

### BACKGROUND

Managing stored data is critical for corporations, applications, cloud services, etc. A shared system of storage, such as a SAN, can be used to manage data in a redundant manner and allow multiple clients to read and/or write data. A SAN is connected to and accessible via a network, such as a local area network (LAN). A SAN can be configured to suit the needs of the operator, but typically includes host bus adapters for communicating with devices in the SAN, switches, routers, gateways, storage processors, and/or storage devices such as hard disks, solid state devices, magnetic tape devices, etc.

As described above, a SAN can be designed and configured based on the needs of a particular operator. In order to ensure that the SAN will meet the demands of the operator, a SAN simulator may be used to simulate various operations of the SAN. Using the SAN simulator, the designer of the SAN can confirm that the SAN will meet the demands of the operator. Maximizing the uptime of a SAN may be important to the operator of the SAN. An output of the SAN simulator can be used to determine probabilities that the SAN will fail and to execute preventative maintenance or take other remedial actions.

Although a SAN simulator is useful for designing and configuring a SAN, it can be expensive, time-consuming, and/or difficult to generate a SAN simulator that is sufficiently accurate to provide useful predictions.

U.S. Pat. No. 10,089,178 issued to International Business Machines Corporation on Oct. 2, 2018, discloses a distributed storage network (DSN) having a plurality of storage units located at geographically different sites. DSN behavioral model information is used to generate a simulation module that is configured to generate the predictive performance of the plurality of outputs. The DSN is modeled using a neural network.

U.S. Pat. No. 8,175,986 issued to International Business Machines Corporation on May 8, 2012, discloses a system for generating a storage policy. A simulator is used to simulate the storage system implementing a given storage policy. The simulation result is then evaluated by a machine learning entity and the machine learning entity generates multiple storage policies. Each of the storage policies is evaluated and one is selected.

U.S. Pat. No. 9,406,029 issued to NETAPP, INC on Aug. 2, 2016, discloses a system for training a modeler engine to predict metrics of a storage system. The modeler engine is trained using machine learning techniques to predict values of metrics of a storage cluster. The modeler engine predicts values of particular system metrics of the storage cluster.

### SUMMARY

Developers of the present technology have appreciated at least one technical problem associated with the prior art approaches.

The present technology relates to creating an accurate, cost-effective iterative SAN simulator, and more specifically to methods and systems for training a machine learning algorithm (MLA) to adjust parameters of the SAN simulator at each iteration of the SAN simulator, thereby increasing the accuracy of the SAN simulator.

In accordance with the non-limiting embodiments of the present technology, a SAN simulator may be generated to simulate a SAN. The SAN simulator may simulate each component (i.e. element) of the SAN, or a subset of the components of the SAN. The SAN simulator may receive SAN system operations to simulate as input. The SAN system operations may be read and/or write operations. The SAN simulator may receive input parameters as input. The input parameters may indicate capabilities of components of the SAN simulator.

At each iteration of the SAN simulator, a portion of the SAN system operations are simulated based on the input parameters. The SAN simulator predicts and outputs metrics of the components of the SAN system. The SAN simulator also outputs output parameters of the SAN simulator.

An MLA may be trained to adjust the parameters of the SAN simulator. At each iteration of the SAN simulator the MLA may receive the output parameters of the SAN simulator. The MLA may determine adjustments to the SAN simulator parameters based on the output parameters and current metrics, and then output the adjustments as input parameters for a next iteration of the SAN simulator. The parameter adjustments may cause the SAN simulator to provide predictions that are more accurate.

In order to train the MLA, the SAN system may be instructed to process operational inputs. Metrics of the SAN system may be measured while the SAN system is processing the operational inputs. The operational inputs and measured metrics may be used as training data for training the MLA.

During training of the MLA, the operational inputs may be input to the SAN simulator. At each iteration of the SAN simulator, the MLA may compare the predicted metrics from the SAN simulator to the measured metrics from the SAN system. The MLA may output parameter adjustments for a next iteration of the SAN system. Over time, the MLA may be trained to adjust the parameters of the SAN simulator in order to reduce the difference between the predicted metrics and the measured metrics.

According to a first broad aspect of the present technology, there is provided a computer implemented method of operating a SAN simulator. The computer implemented method is executable by an electronic device connectable to the SAN simulator. The computer implemented method comprises: generating training data representative of a SAN system, the training data comprising: (i) an operational input to the SAN system, and (ii) a metric measured during operation of the SAN system, the metric associated with the operation of the SAN system based on the operational input; generating the SAN simulator corresponding to the SAN system, the SAN simulator for outputting, based on simulated input and one or more parameters of the SAN simulator, a predicted metric of at least one component of the SAN system, wherein the one or more parameters correspond to functions of simulated components of the SAN simulator; and training, based on the training data, an MLA to determine adjustments to the one or more parameters of the SAN simulator.

In some implementations of the method, the method further comprises after the MLA is trained and at each iteration of the SAN simulator: inputting a current state of the SAN simulator to the MLA, thereby generating the adjustments to the one or more parameters, and causing the SAN simulator to use the adjustments to the one or more parameters during a next iteration.

In some implementations of the method, the training the MLA comprises training the MLA to minimize a difference between metrics measured during operation of the SAN system and predicted metrics from the SAN simulator, the predicted metrics being based on the simulated components of the SAN system.

In some implementations of the method, the predicted metric comprises any one or more of the following: a number of input/output operations, storage processor load, traffic, and average response time.

In some implementations of the method, the adjustments to the one or more parameters comprise adjustments to any one or more of the following: a maximum read speed, a maximum write speed, an amount of computational power, bandwidth, and latency.

In some implementations of the method, the generating the training data comprises inputting the operational inputs to the SAN system and measuring the metric, and wherein the operational inputs comprise at least one of a read operation and a write operation.

In some implementations of the method, the operational inputs further comprise one or more parameters of the SAN system.

In some implementations of the method, the method further comprises simulating, by the SAN simulator, a failure of the SAN system; storing a record of the simulated failure; and determining, based on the record, an adjustment for the SAN system.

In some implementations of the method, the method further comprises, after the MLA is trained, and at each iteration of the SAN simulator: determining, by the SAN simulator, based on the simulated input and the adjustments to the one or more parameters, the predicted metric for a current iteration; and inputting, to the MLA, the predicted metric to generate the adjustments to the one or more parameters for a next iteration.

In some implementations of the method, each of the simulated components of the SAN simulator corresponds to a component of the SAN system.

In some implementations of the method, the MLA comprises a neural network, and wherein the training comprises determining a plurality of weights for the neural network.

In some implementations of the method, the training the MLA comprises: determining a difference between the measured metric and the predicted metric; and using the difference as at least a part of a cost function for training the MLA.

In accordance with yet another broad aspect of the present technology, there is provided a system for operating a SAN simulator. The system comprises a processor and a non-transitory computer-readable medium comprising instructions. The processor, upon executing the instructions, is configured to: generate training data representative of a SAN system, the training data comprising: (i) an operational input to the SAN system, and (ii) a metric measured during operation of the SAN system, the metric associated with the operation of the SAN system based on the operational input; generate the SAN simulator corresponding to the SAN system, the SAN simulator for outputting, based on a simulated input and one or more parameters of the SAN simulator, a predicted metric of at least one component of the SAN system, wherein the one or more parameters correspond to functions of simulated components of the SAN simulator; and training, based on the training data, an MLA to determine adjustments to the one or more parameters of the SAN simulator.

In some implementation of the system, the processor, upon executing the instructions, is further configured to simulate, by the SAN simulator, a failure of the SAN system; store a record of the simulated failure; and determine, based on the record, an adjustment for the SAN system.

In some implementation of the system, the predicted metric comprises any one or more of the following: a number of input/output operations, storage processor load, traffic, and average response time.

In some implementation of the system, the one or more parameters of the SAN simulator comprise any one or more of the following: a read speed, a write speed, an amount of computational power, bandwidth, and latency.

In some implementation of the system, the processor, upon executing the instructions, is further configured to determine a difference between the measured metric and the predicted metric; and use the difference as at least a part of a cost function for training the MLA.

In accordance with yet another broad aspect of the present technology, there is provided a system for simulating a SAN system. The system comprises an iterative SAN simulator for modeling a plurality of components of the SAN system and an MLA trained to adjust parameters of the iterative SAN simulator. The iterative SAN simulator is configured to: receive, from an operator of the SAN simulator, a plurality of SAN system operations, and at each iteration of the iterative SAN simulator: receive input parameters from the MLA, wherein the input parameters correspond to functions of simulated components of the iterative SAN simulator, and determine, based on the plurality of SAN system operations and the input parameters, (i) predicted metrics of the plurality of components of the SAN system and (ii) output parameters. The MLA is configured to, for each iteration of the iterative SAN simulator: receive the output parameters and the predicted metrics, and determine, based on the output parameters and the predicted metrics, the input parameters for a next iteration of the iterative SAN simulator.

In some implementation of the system, the system further comprises a failure detection system configured to: determine, based on the predicted metrics, that a simulated failure has occurred; and determine, based on the simulated failure, an adjustment for the SAN system.

In some implementation of the system the iterative SAN simulator is configured to, at each iteration, simulate processing a portion of the plurality of SAN system operations, and wherein the plurality of SAN system operations comprise at least one of a read operation and a write operation.

In the context of the present specification, a “server” is a computer program that is running on appropriate hardware and is capable of receiving requests (e.g. from electronic devices) over a network, and carrying out those requests, or causing those requests to be carried out. The hardware may be one physical computer or one physical computer system, but neither is required to be the case with respect to the present technology. In the present context, the use of the expression a “server” is not intended to mean that every task (e.g. received instructions or requests) or any particular task will have been received, carried out, or caused to be carried out, by the same server (i.e. the same software and/or hardware); it is intended to mean that any number of software elements or hardware devices may be involved in receiving/sending, carrying out or causing to be carried out any task or request, or the consequences of any task or request; and all of this software and hardware may be one server or multiple servers, both of which are included within the expression “at least one server.”

In the context of the present specification, “electronic device” is any computer hardware that is capable of running software appropriate to the relevant task at hand. Thus, some (non-limiting) examples of electronic devices include personal computers (desktops, laptops, netbooks, etc.), smartphones, and tablets, as well as network equipment such as routers, switches, and gateways. It should be noted that a device acting as an electronic device in the present context is not precluded from acting as a server to other electronic devices. The use of the expression “an electronic device” does not preclude multiple electronic devices being used in receiving/sending, carrying out or causing to be carried out any task or request, or the consequences of any task or request, or steps of any method described herein.

In the context of the present specification, a “database” is any structured collection of data, irrespective of its particular structure, the database management software, or the computer hardware on which the data is stored, implemented or otherwise rendered available for use. A database may reside on the same hardware as the process that stores or makes use of the information stored in the database or it may reside on separate hardware, such as a dedicated server or plurality of servers.

In the context of the present specification, the expression “information” includes information of any nature or kind whatsoever capable of being stored in a database. Thus information includes, but is not limited to audiovisual works (images, movies, sound records, presentations etc.), data (location data, numerical data, etc.), text (opinions, comments, questions, messages, etc.), documents, spreadsheets, etc.

In the context of the present specification, the expression “computer usable information storage medium” is intended to include media of any nature and kind whatsoever, including RAM, ROM, disks (CD-ROMs, DVDs, floppy disks, hard drives, etc.), USB keys, solid state-drives, tape drives, etc.

In the context of the present specification, unless expressly provided otherwise, an “indication” of an information element may be the information element itself or a pointer, reference, link, or other indirect mechanism enabling the recipient of the indication to locate a network, memory, database, or other computer-readable medium location from which the information element may be retrieved. For example, an indication of a document could include the document itself (i.e. its contents), or it could be a unique document descriptor identifying a file with respect to a particular file system, or some other means of directing the recipient of the indication to a network location, memory address, database table, or other location where the file may be accessed. As one skilled in the art would recognize, the degree of precision required in such an indication depends on the extent of any prior understanding about the interpretation to be given to information being exchanged as between the sender and the recipient of the indication. For example, if it is understood prior to a communication between a sender and a recipient that an indication of an information element will take the form of a database key for an entry in a particular table of a predetermined database containing the information element, then the sending of the database key is all that is required to effectively convey the information element to the recipient, even though the information element itself was not transmitted as between the sender and the recipient of the indication.

In the context of the present specification, the words “first,” “second,” “third,” etc. have been used as adjectives only for the purpose of allowing for distinction between the nouns that they modify from one another, and not for the purpose of describing any particular relationship between those nouns. Thus, for example, it should be understood that, the use of the terms “first server” and “third server” is not intended to imply any particular order, type, chronology, hierarchy or ranking (for example) of/between the server, nor is their use (by itself) intended imply that any “second server” must necessarily exist in any given situation. Further, as is discussed herein in other contexts, reference to a “first” element and a “second” element does not preclude the two elements from being the same actual real-world element. Thus, for example, in some instances, a “first” server and a “second” server may be the same software and/or hardware, in other cases they may be different software and/or hardware.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 is an illustration of components and features of a computing device in accordance with non-limiting embodiments of the present technology.

FIG. 2 depicts a diagram of a storage area network (SAN) system implemented in accordance with non-limiting embodiments of the present technology.

FIG. 3 depicts a diagram of a process of the SAN system generating training data in accordance with embodiments of the present technology.

FIG. 4 depicts a diagram of a SAN simulator with an MLA being trained in accordance with embodiments of the present technology.

FIG. 5 depicts a diagram of the SAN simulator with a trained MLA in accordance with embodiments of the present technology.

FIGS. 6, 7, and 8 depict a flow diagram of a method for simulating a SAN system in accordance with some non-limiting embodiments of the present technology.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

The functions of the various elements shown in the figures, including any functional block labeled as a “processor” or a “graphics processing unit”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general purpose processor, such as a central processing unit (CPU) or a processor dedicated to a specific purpose, such as a graphics processing unit (GPU). Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown.

With these fundamentals in place, we will now consider some non-limiting examples to illustrate various implementations of aspects of the present technology.

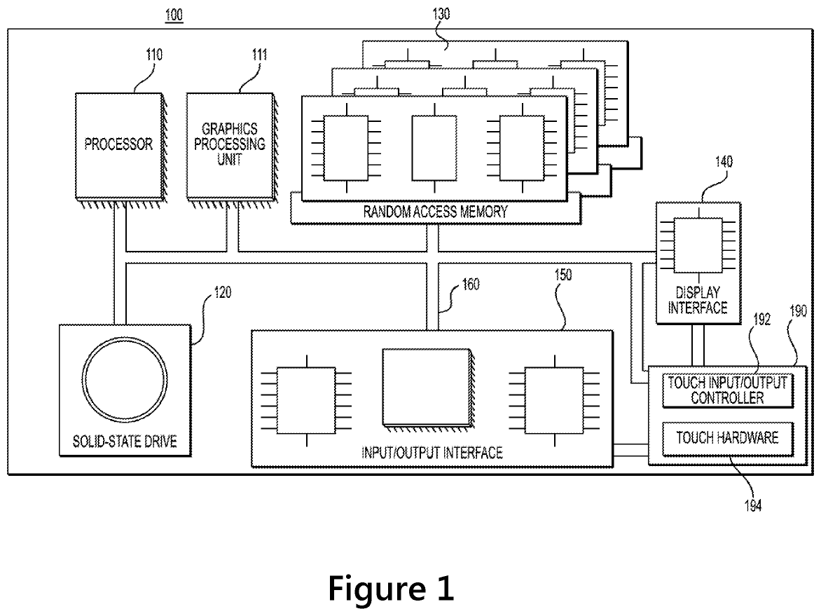

With reference to FIG. 1, there is shown a computing device 100 suitable for use with some implementations of the present technology. The computing device 100 comprises various hardware components including one or more single or multi-core processors collectively represented by processor 110, a graphics processing unit (GPU) 111, a solid-state drive 120, a random access memory 130, a display interface 140, and an input/output interface 150.

Communication between the various components of the computing device 100 may be enabled by one or more internal and/or external buses 160 (e.g. a PCI bus, universal serial bus, IEEE 1394 “Firewire” bus, SCSI bus, Serial-ATA bus, etc.), to which the various hardware components are electronically coupled.

The input/output interface 150 may be coupled to a touchscreen 190 and/or to the one or more internal and/or external buses 160. The touchscreen 190 may be part of the display. In some embodiments, the touchscreen 190 is the display. The touchscreen 190 may equally be referred to as a screen 190. In the embodiments illustrated in FIG. 1, the touchscreen 190 comprises touch hardware 194 (e.g., pressure-sensitive cells embedded in a layer of a display allowing detection of a physical interaction between a user and the display) and a touch input/output controller 192 allowing communication with the display interface 140 and/or the one or more internal and/or external buses 160. In some embodiments, the input/output interface 150 may be connected to a keyboard (not shown), a mouse (not shown) or a trackpad (not shown) allowing the user to interact with the computing device 100 in addition to or instead of the touchscreen 190.

According to implementations of the present technology, the solid-state drive 120 stores program instructions suitable for being loaded into the random access memory 130 and executed by the processor 110 and/or the GPU 111. For example, the program instructions may be part of a library or an application.

The computing device 100 may be a server, a desktop computer, a laptop computer, a tablet, a smartphone, a personal digital assistant or any device that may be configured to implement the present technology, as should be understood by a person skilled in the art.

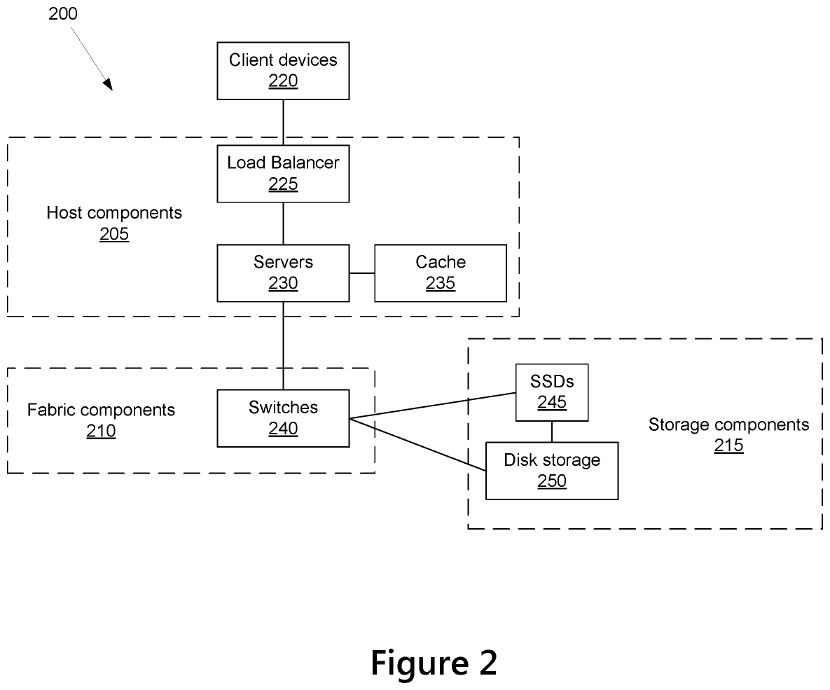

With reference to FIG. 2, there is depicted an example of a SAN system 200, the SAN system 200 implemented according to non-limiting embodiments of the present technology. As discussed above, the SAN system 200 is a network that provides access to storage devices. The SAN system 200 comprises host components 205, fabric components 210, and storage components 215. As described above, the SAN system 200 provides storage of data and access to the stored data.

Client devices 220 access the SAN system 200 to perform data operations such as read operations and/or write operations. The data operations are processed by the SAN system 200 and written to the storage components 215. The client devices 220 may communicate with the SAN system 200 via a network, such as a local area network (LAN), virtual network, and/or the internet. Multiple client devices 220 may simultaneously access the SAN system 200.

The client devices 220 may transmit requests to a load balancer 225, such as read and/or write requests. The load balancer 225 may select one of the servers 230 and forward the request to the selected server 230. The load balancer 225 may select the server 230 based on which of the servers 230 has the least processing load, in a round-robin fashion, or based on any other load balancing technique. The selected server 230 may then communicate directly with the client device 220 while processing the request.

The servers 230 may be computing devices 100. The servers 230 may provide access to the SAN system 200. The servers 230 may communicate with storage components 215, such as by using a host bus adapter (HBA) which may be integrated in each server 230. The servers 230 may be able to perform data operations on the storage components 215.

The servers 230 may include, or be in communication with, a cache 235. The cache 235 may store recently accessed data, frequently accessed data, and/or any other data. Any suitable caching strategy may be used for managing the data in the cache 235. In some instances, write operations may be first written to the cache and then later stored in the storage components 215.

The servers 230 may communicate with the storage components 215 via the fabric components 210, which may be a PCI express fabric. The fabric components 210 may include switches 240 and/or any other networking devices such as routers (not illustrated), bridges (not illustrated), gateways (not illustrated), cables (not illustrated), etc. The fabric components 210 may route traffic from the servers 230 to the storage components 215.

The storage components 215 may comprise solid-state drives (SSDs) 245, disk storage 250 such as hard disks, magnetic tape storage (not illustrated) and/or any other type of data storage device. The storage components 215 may be linked together, such as by using a redundant array of independent disks (RAID) architecture. The storage components 215 may be organized into one or more RAID clusters. Each of the storage components 215 may be assigned an address. The address of a storage component 215 may be used to access that storage component 215 by the servers 230 and/or other storage components 215.

Although FIG. 2 illustrates one example of the SAN system 200, it should be understood that the SAN system 200 is configurable and that there are many different possible architectures of the SAN system 200.

When designing or modifying the SAN system 200, the operator may wish to simulate the SAN system 200 to ensure that the SAN system 200 can meet the needs of the operator and perform as expected (for example, based on service level agreement or other commitments to the clients of the SAN system 200). The operator may wish to minimize the likelihood of a failure of the SAN system 200, and maximize the uptime of the SAN system 200. To simulate the SAN system 200, a SAN simulator may be generated that simulates the various components of the SAN system 200, such as the load balancer 225, servers 230, cache 235, switches 240, SSDs 245, disk storage 250, and/or any other components of the SAN system 200. The output of the SAN simulator may be used to estimate the probability of a failure or anomaly occurring under various conditions. In some embodiments of the present technology, a separately trained Machine Learning Algorithm (MLA) or an heuristics based model can be used for predicting failure or anomaly based on the output of the SAN simulator.

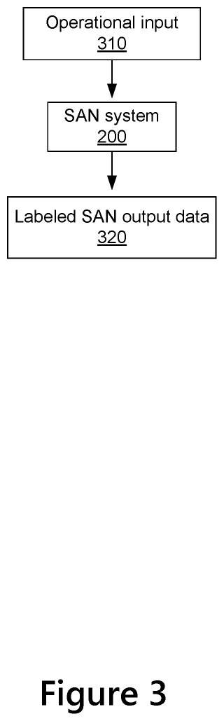

FIG. 3 depicts a diagram of a process for generating training data using the SAN system 200 in accordance with embodiments of the present technology. As described above, an MLA may be trained to adjust parameters of the SAN simulator. The MLA may be trained using labeled training data. The labeled training data may describe the performance of the SAN system 200 given a set of operational inputs 310.

The operational inputs 310 may be a series of read/write operations and/or other data operations. The operational inputs 310 may be simulated inputs, actual inputs, or a combination of the two. The operational inputs 310 may be generated, such as by a user or an algorithm. The operational inputs 310 may be recorded during operation of the SAN system 200, such as actual data operations performed during normal operation of the SAN system 200.

The operational inputs 310 may be input to the SAN system 200. The operational inputs 310 may be input to the load balancer 225 and the servers 230. The operational inputs 310 may be input sequentially with a delay in between each operation. The timing for each request in the operational inputs 310 may be indicated in the operational inputs 310. For example, each operation in the operational inputs 310 may include a timestamp.

Various metrics of the SAN system 200 may be measured while the SAN system 200 performs the operations based on the operational inputs 310. The metrics may be measured at regular intervals, whenever there are changes to the metrics, and/or using any other measurement technique. The metrics may describe the performance of one or more components of the SAN system 200, such as the performance of the load balancer 225, servers 230, cache 235, switches 240, SSDs 245, disk storage 250, and/or any other component of the SAN system 200. The metrics may include a number of input/output operations being performed, storage processor load, traffic, average response time of a component or components, amount of storage processor memory (e.g. RAM) that is used, amount of storage processor memory that is free, total disk volume storage capacity, used amount of disk volume storage, available amount of disk volume storage, storage processor load (i.e. CPU usage), amount of data transmitted over networking devices (e.g. switches, etc.), amount of input and/or output errors for storage devices, average request queue length for storage devices, and/or any other metric of the SAN system 200.

The measured metrics form labeled SAN output data 320. The labeled SAN output data 320 may include the measured metrics from the SAN system 200, timestamps corresponding to each measured metric, other system information regarding the SAN system 200, such as any errors that occur, the status of various devices or device groups in the SAN system 200, and/or any other data corresponding to the SAN system 200. As described in further detail below, the labeled SAN output data 320 may be used to train the MLA to adjust parameters of a SAN simulator that simulates the SAN system 200.

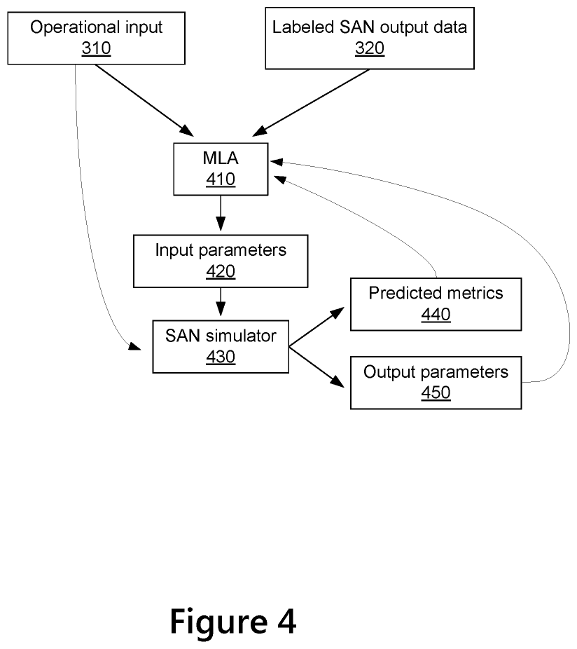

FIG. 4 depicts a diagram of a SAN simulator 430 and MLA 410 during a training phase of the MLA 410 in accordance with embodiments of the present technology. After generating the labeled SAN output data 320, as described above in regard to FIG. 3, the MLA 410 may be trained to adjust parameters of the SAN simulator 430.

The MLA 410 may receive, as input, the operational input 310, the labeled SAN output data 320, the predicted metrics 440, and the output parameters 450. The MLA 410 may use all or a portion of the operational input 310, predicted metrics 440, and output parameters 450 to generate input parameters 420 for the SAN simulator 430. The input parameters 420 may control various functions of components of the SAN simulator 430. The input parameters 420 may include the read speed of a component, such as a maximum read speed, the write speed of a component, such as a maximum write speed, an amount of computational power of a component, bandwidth of a link between components, latency of network links, disk capacity, ambience parameters (e.g. temperature, atmospheric pressure, humidity, vibration, etc.), and/or any other parameters of the SAN simulator 430.

The SAN simulator 430 may be an iterative simulator. At each iteration of the SAN simulator 430, the SAN simulator 430 may simulate the processing of a portion of the operational input 310. The length of each iteration may be an amount of time, a number of operations, or any other measure.

A new set of input parameters 420 may be input to the SAN simulator 430 at each iteration. At each iteration the SAN simulator 430 may simulate processing of the operational input 310 based on the input parameters 420. The simulated components in the SAN simulator 430 may produce predicted metrics 440 and output parameters 450. The predicted metrics 440 may correspond to the labeled SAN output data 320. For example if labeled SAN output data 320 includes a measured average response time for the servers 230, the predicted metrics 440 may include a predicted average response time for the servers 230. The output parameters 450 may similarly correspond to the input parameters 420. For example if the input parameters 420 include the write speed of the disk storage 250, the output parameters 450 may also include the write speed of the disk storage 250.

The predicted metrics 440 and output parameters 450 may be input to the MLA 410, such as at the end of an iteration of the SAN simulator 430. During the training phase illustrated in FIG. 4, the MLA 410 may compare the predicted metrics 440 to the labeled SAN output data 320. The MLA 410 may adjust itself based on a difference between the predicted metrics 440 and the labeled SAN output data 320. This process is referred to as training the MLA 410. A loss function for the MLA 410 may be based on the difference between the predicted metrics 440 and the measured metrics in the labeled SAN output data 320. The MLA 410 may be adjusted based on the results of the loss function. For example if the MLA 410 is a neural network, various weights of the MLA 410 may be adjusted to minimize the loss function. The MLA 410 may then generate input parameters 420, based on the predicted metrics 440, output parameters 450, and/or the operational input 310, for the next iteration of the SAN simulator 430.

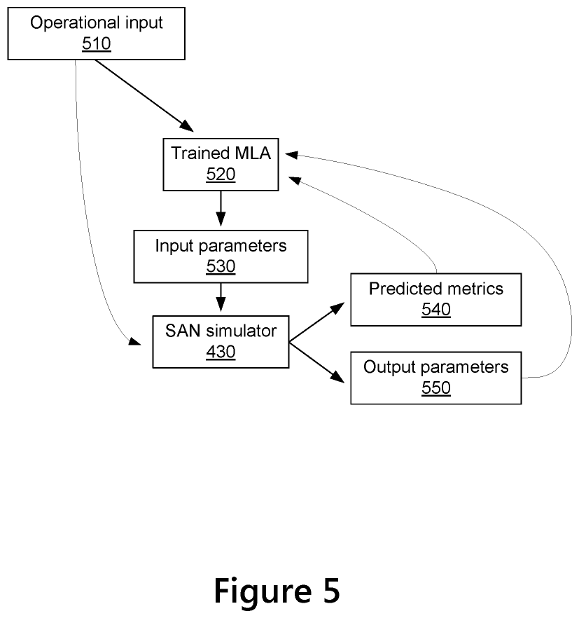

After the MLA 410 is trained, the MLA 410 may be used to adjust parameters of the SAN simulator 430. FIG. 5 depicts a diagram of the SAN simulator 430 being operated by a trained MLA 520 in accordance with embodiments of the present technology. The trained MLA 520 may have the same structure as the MLA 410, with weightings or other configurable elements that have been adjusted during training.

During operation of the SAN simulator 430, the trained MLA 520 and SAN simulator 430 are provided operational input 510. Unlike the operational input 310, the operational input 510 might not have been input to the SAN system 200. Rather the operational input 510 may be executed solely by the SAN simulator 430. At each iteration of the SAN simulator 430, the SAN simulator 430 may use the input parameters 530 and the operational input 510 to generate predicted metrics 540 and output parameters 550. At each iteration of the SAN simulator 430, the trained MLA 520 may take the operational input 510, predicted metrics 540, and output parameters 550 as input and generate input parameters 530 as output.

### Method (Non-Limiting Embodiment)

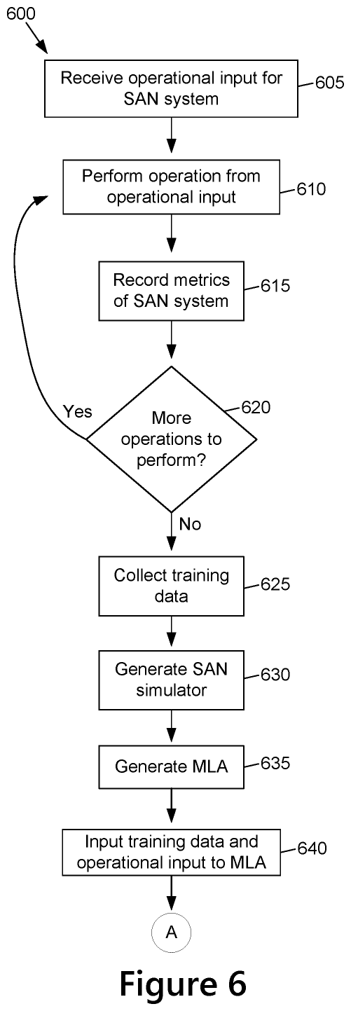

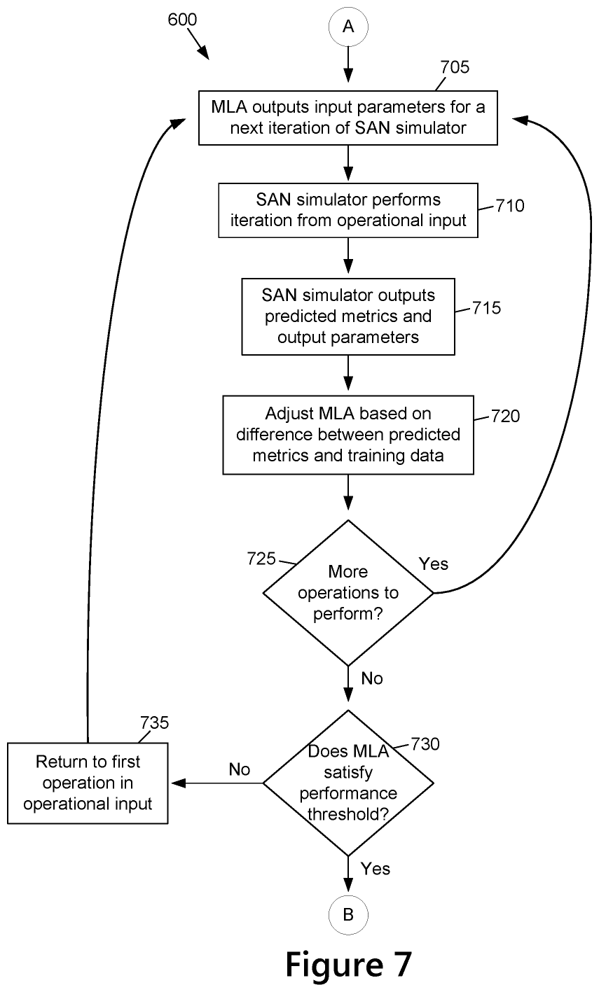

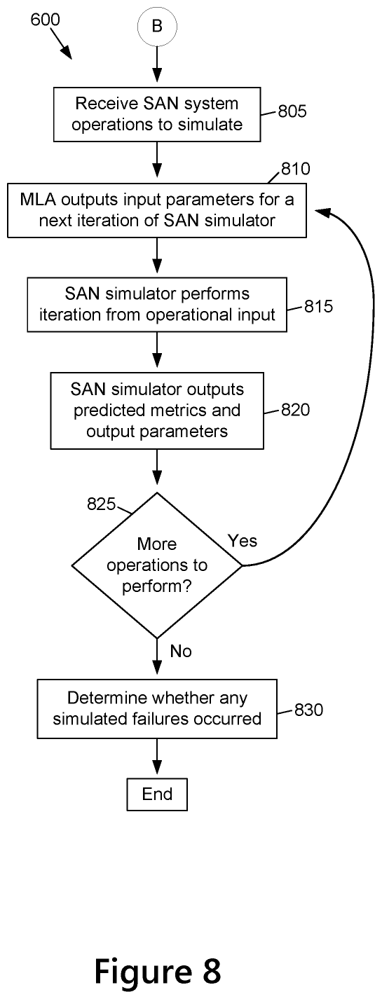

With reference to FIGS. 6-8, there is depicted a flow chart of a method 600, the method 600 being implementable in accordance with non-limiting embodiments of the present technology.

### Step 605—Receive Operational Input for a SAN System

Steps 605-625 describe generating training data, as illustrated in FIG. 3. At step 605 the operational input 310 may be received by the SAN system 200. As described above, the operational input 310 may include read operations, write operations, and/or any other type of data operations.

The operational input 310 may include a mode of the SAN system 200, packet size, overall data size, and number of parallel jobs being performed by the SAN system 200. The operational input 310 may include parameters of the SAN system 200. The operational input 310 may be ordered. The operational input 310 may include timestamps for all or a portion of the operations.

The operational input 310 may be retrieved from a storage such as a database, received from one or more systems such as via a network, or otherwise received. The operational input 310 may be transmitted to the SAN system 200 by client devices 220.

Step 610—Perform an Operation from the Operational Input

At step 610 an operation may be performed based on the operational input 310. The SAN system 200 may perform the operation. The SAN system 200 may write data to the storage components 215, retrieve data from the storage components 215, or perform any other data operation. It should be understood that, although described as a single operation, multiple operations from the operational input 310 may be performed at step 610.

### Step 615—Record Metrics of SAN System

At step 615 various metrics of the SAN system 200 may be measured. The metrics may indicate the performance of components of the SAN system 200 before, during, and/or after performing the operation from the operational input at step 610. The metrics may be recorded at a predetermined interval.

Step 620—Determine Whether there are More Operations in the Operational Input

At step 620 a determination may be made as to whether there are additional operations to perform in the operational input. If operations remain, the method 600 may return to step 610 and perform the next operation in the operational input. If all operations have been performed, the method 600 may proceed to step 625.

### Step 625—Collect Training Data

At step 625 the measured metrics may be collected to form the labeled SAN output data 320. The measured metrics may be stored in a database or any other data structure. The measured metrics may indicate the performance of the components of the SAN system 200 while performing the operational input 310. The measured metrics may include amount of input and/or output operations, storage processor load and traffic, average response time, and/or other measured metrics. The metrics may be measured periodically, such as at a predetermined time interval. The metrics may be extracted, such as from log data of the SAN system 200.

### Step 630—Generate SAN Simulator

Steps 630-735 describe training the MLA 410, as illustrated in FIG. 4. The MLA 410 may be trained using reinforcement learning, and/or any other method of training an MLA 410. At step 630 the SAN simulator 430 may be generated. A description of the architecture of the SAN system 200 may be received. The description may include each component of the SAN system 200. The description may include parameters of those components, such as read and write speeds for storage media, computational power for storage controllers and storage drive enclosures, bandwidth and latency of network links, etc.

The SAN simulator 430 may include a simulated version of each component of the SAN system 200, or a subset of components of the SAN system 200. The SAN simulator 430 may simulate the upper level architecture of the SAN system 200. The SAN simulator 430 may simulate components of the SAN system 200, effective parameters of the components, and/or the connections between components.

Each component of the SAN system 200 may be simulated by a module in the SAN simulator 430. As described above, the SAN simulator 430 may receive operational inputs 310 and input parameters 420, and then perform an iteration by simulating the SAN system 200 performing an operation in the operational inputs 310. The SAN simulator 430 may output the same set of predicted metrics as the metrics measured from the SAN system 200.

### Step 635—Generate MLA

At step 635 the MLA 410 may be generated. The MLA 410 may be a neural network or any other suitable type of machine learning model. The parameters of the MLA 410 may be pre-determined and/or configured by a user. The MLA 410 may be configured to receive as input the operational input 310, predicted metrics 440, output parameters 450, and labeled SAN output data 320. The MLA 410 may be configured to output adjustments to the output parameters 450 as input parameters 420.

### Step 640—Input Training Data and Operational Input to MLA

At step 640 the MLA 410 may be provided the labeled SAN output data 320 and operational input 310 as training data. The labeled SAN output data 320 may include metrics measured during operation of the SAN system 200. The MLA 410 may be provided the operational input 310 that was used when generating the labeled SAN output data 320. The MLA 410 may be provided an address or other identifying information for retrieving the labeled SAN output data 320 and/or operational input 310.

### Step 705—MLA Outputs Input Parameters for a Next Iteration of the SAN Simulator

At step 705 the MLA 410 may output the input parameters 420 for an iteration of the SAN simulator 430. If this is a first iteration of the SAN simulator 430, initial values for the input parameters 420 may be pre-determined, described in the operational input 310, and/or determined based on the operational input 310.

For iterations subsequent to the first iteration of the SAN simulator 430, the MLA 410 may process the operational input 310, predicted metrics 440, and/or output parameters 450 from the last iteration to generate the input parameters 420 for a next iteration. A portion of the operational input 310 may be input to the MLA 410, such as the portion of the operational input 310 that was processed during the previous iteration of the SAN simulator 430 or the portion of the operational input 310 that will be processed during the next iteration of the SAN simulator 430.

Step 710—SAN Simulator Performs an Iteration from the Operational Input

At step 710 the SAN simulator 430 may perform an iteration. The iteration may simulate processing a portion of the operational input 310, such as one read or write request. The SAN simulator 430 may generate predicted metrics 440 for the iteration, where each predicted metric 440 predicts the value of a measured metric of the SAN system 200 before, during, and/or after performing the iteration. The predicted metrics 440 may be predicted at predetermined time intervals. Output parameters 450 of the SAN system 200 may be generated.

### Step 715—SAN Simulator Outputs Predicted Metrics and Output Parameters

At step 715 the SAN simulator 430 may output the predicted metrics 440 and/or the output parameters 450 from the iteration performed at step 710. The predicted metrics 440 and/or output parameters 450 may be output to the MLA 410. The predicted metrics 440 and/or output parameters 450 may be extracted from the SAN simulator 430 output. For example log data may be output by the SAN simulator 430, and the predicted metrics 440 and/or output parameters 450 may be extracted from the log data.

Step 720—Adjust MLA Based on Difference between Predicted Metrics and Training Data

At step 720 the MLA 410 may be adjusted based on the difference between the predicted metrics 440 and the labeled SAN output data 320. A cost function of the MLA 410 may be based on the difference between the predicted metrics 440 and the labeled SAN output data 320. If the MLA 410 is a neural network, various weights of the neural network may be adjusted based on the cost function. Residuals may be calculated between the predicted metrics 440 and the measured metrics from the SAN system 200 in the labeled SAN output data 320. The weights of the neural network may be updated to minimize the residuals. The MLA 410 may be adjusted so that the input parameters 420 generated by the MLA 410 minimize a difference between the predicted metrics 440 and the measured metrics in the labeled SAN output data 320.

Step 725—Determine whether there are More Operations to Perform in the Operational Input

At step 725 a determination may be made as to whether the operational input 310 has been fully processed or whether there are additional operations to process in the operational input 310. If there are additional operations in the operational input 310, the MLA 410 may output parameters for a next iteration of the SAN simulator 430 at step 705 and the SAN simulator 430 may then perform the next iteration at step 710. If there are no additional operations to perform in the operational input 310, the method 600 may proceed to step 730.

Step 730—Determine whether the MLA Satisfies a Performance Threshold

At step 730 a determination may be made as to whether the MLA 410 satisfies a performance threshold. The accuracy of the predicted metrics 440, when compared to the labeled SAN output data 320, may be measured while the SAN simulator 430 simulates processing of the operational input 310. If the predicted metrics 440 are not close enough to the labeled SAN output data 320 to satisfy the performance threshold, the training of the MLA 410 may continue by starting from the beginning of the operational input 310 and continuing to adjust the MLA 410. If the MLA 410 does satisfy the performance threshold then the MLA 410 is considered to be trained.

### Step 735—Return to First Operation in Operational Input

If at step 730 the MLA 410 did not satisfy the performance threshold, at step 735 the training of the MLA 410 may begin again at the first operation in the operational input. The weights, or other adjustable parameters, determined during the previous round of training the MLA 410 may be used as the initial weights for the next round of training the MLA 410.

### Step 805—Receive SAN System Operations to Simulate

If at step 730 the MLA 410 did satisfy the performance threshold, the training of the MLA 410 is considered complete and the MLA 410, which is now the trained MLA 520, is ready for operation with the SAN simulator 430. Steps 805-830 describe operating the SAN simulator 430 with the trained MLA 520, as illustrated in FIG. 5. At step 805 operational input 510 may be received. The operational input 510 may comprise operations to be simulated by the SAN simulator 430. The operational input 510 may be received by the trained MLA 520 and/or SAN simulator 430.

### Step 810—MLA Outputs Input Parameters for a Next Iteration of SAN Simulator

At step 810 the trained MLA 520 may output input parameters for a next iteration of the SAN simulator 430. The trained MLA 520 may output adjustments to the output parameters 550 of the SAN simulator 430 from the prior iteration. Actions performed at step 810 may be similar to those described above in regard to step 705.

Step 815—SAN Simulator Performs Iteration from Operational Input

At step 815 the SAN simulator 430 may perform an iteration by simulating the processing of a portion of the operational input 510. The iteration may include simulating one or more data operations from the operational input 510. Actions performed at step 815 may be similar to those described above in regard to step 710.

### Step 820—SAN Simulator Outputs Predicted Metrics and Output Parameters

At step 820 the SAN simulator 430 may output the predicted metrics 540 and/or output parameters 550 from the last iteration. Actions performed at step 820 may be similar to those described above in regard to step 715.

Step 825—Determine whether there are More Operations to Perform

At step 825 a determination may be made as to whether all of the operations in the operational input 510 have been simulated by the SAN simulator 430, or whether there are additional operations to perform. If there are additional operations to perform, at step 810 input parameters for the next iteration of the SAN simulator 430 may be generated. If there are no more operations to perform, the method 600 may proceed to step 830.

Step 830—Determine whether any Simulated Failures Occurred

At step 830 the predicted metrics 540 from the SAN simulator 430 may be examined to determine whether any failures were simulated while processing the operational input 510. A record may be stored describing any simulated failures that occurred. An amount of downtime simulated by the SAN simulator 430 may be determined. The predicted metrics 540 from the SAN simulator 430 may be used to determine whether the SAN system 200 meets the specifications of the owners, such as whether the SAN system 200 can operate with a specified number of client devices 220, read and/or write data at a specified speed, and/or other specifications. If failures were simulated, the SAN system 200 may be adjusted. The adjustment to the SAN system 200 may be determined using a record of simulated failures. For example, if the predicted metrics 540 indicate that the servers 230 were overloaded, more servers 230 could be added to the SAN system 200.

While the above-described implementations have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

It should be expressly understood that not all technical effects mentioned herein need to be enjoyed in each and every embodiment of the present technology. For example, embodiments of the present technology may be implemented without the user enjoying some of these technical effects, while other embodiments may be implemented with the user enjoying other technical effects or none at all.

Some of these steps and signal sending-receiving are well known in the art and, as such, have been omitted in certain portions of this description for the sake of simplicity. The signals can be sent-received using optical means (such as a fibre-optic connection), electronic means (such as using wired or wireless connection), and mechanical means (such as pressure-based, temperature based or any other suitable physical parameter based).

Modifications and improvements to the above-described implementations of the present technology may become apparent to those skilled in the art. The foregoing description is intended to be used as examples rather than limiting. The scope of the present technology is therefore intended to be limited solely by the scope of the appended claims.

1. A computer implemented method of operating a storage area network (SAN) simulator, the computer implemented method executable by an electronic device connectable to the SAN simulator, the computer implemented method comprising:
generating training data representative of a SAN system, the training data comprising:
(i) an operational input to the SAN system, and (ii) a metric measured during operation of the SAN system, the metric associated with the operation of the SAN system based on the operational input;
generating the SAN simulator corresponding to the SAN system, the SAN simulator for outputting, based on simulated input and one or more parameters of the SAN simulator, a predicted metric of at least one component of the SAN system, wherein the one or more parameters correspond to functions of simulated components of the SAN simulator; and
training, based on the training data, a machine learning algorithm (MLA) to determine adjustments to the one or more parameters of the SAN simulator.

2. The method of claim 1, further comprising, after the MLA is trained and at each iteration of the SAN simulator:
inputting a current state of the SAN simulator to the MLA, thereby generating the adjustments to the one or more parameters, and
causing the SAN simulator to use the adjustments to the one or more parameters during a next iteration.

3. The method of claim 1, wherein the training the MLA comprises training the MLA to minimize a difference between metrics measured during operation of the SAN system and predicted metrics from the SAN simulator, the predicted metrics being based on the simulated components of the SAN system.

4. The method of claim 1, wherein the predicted metric comprises any one or more of the following: a number of input/output operations, storage processor load, traffic, and average response time.

5. The method of claim 1, wherein the adjustments to the one or more parameters comprise adjustments to any one or more of the following: a maximum read speed, a maximum write speed, an amount of computational power, bandwidth, and latency.

6. The method of claim 1, wherein the generating the training data comprises inputting the operational inputs to the SAN system and measuring the metric, and wherein the operational inputs comprise at least one of a read operation and a write operation.

7. The method of claim 6, wherein the operational inputs further comprise one or more parameters of the SAN system.

8. The method of claim 1, further comprising:
simulating, by the SAN simulator, a failure of the SAN system;
storing a record of the simulated failure; and
determining, based on the record, an adjustment for the SAN system.

9. The method of claim 1, further comprising, after the MLA is trained, and at each iteration of the SAN simulator:
determining, by the SAN simulator, based on the simulated input and the adjustments to the one or more parameters, the predicted metric for a current iteration; and
inputting, to the MLA, the predicted metric to generate the adjustments to the one or more parameters for a next iteration.

10. The method of claim 1, wherein each of the simulated components of the SAN simulator corresponds to a component of the SAN system.

11. The method of claim 1, wherein the MLA comprises a neural network, and wherein the training comprises determining a plurality of weights for the neural network.

12. The method of claim 1, wherein the training the MLA comprises:
determining a difference between the measured metric and the predicted metric; and
using the difference as at least a part of a cost function for training the MLA.

13. A system for operating a storage area network (SAN) simulator, the system comprising:
a processor; and
a non-transitory computer-readable medium comprising instructions,
the processor, upon executing the instructions, being configured to:
generate training data representative of a SAN system, the training data comprising: (i) an operational input to the SAN system, and (ii) a metric measured during operation of the SAN system, the metric associated with the operation of the SAN system based on the operational input;
generate the SAN simulator corresponding to the SAN system, the SAN simulator for outputting, based on a simulated input and one or more parameters of the SAN simulator, a predicted metric of at least one component of the SAN system, wherein the one or more parameters correspond to functions of simulated components of the SAN simulator; and
training, based on the training data, a machine learning algorithm (MLA) to determine adjustments to the one or more parameters of the SAN simulator.

14. The system of claim 13, wherein the processor, upon executing the instructions, is further configured to:
simulate, by the SAN simulator, a failure of the SAN system;
store a record of the simulated failure; and
determine, based on the record, an adjustment for the SAN system.

15. The system of claim 13, wherein the predicted metric comprises any one or more of the following: a number of input/output operations, storage processor load, traffic, and average response time.

16. The system of claim 13, wherein the one or more parameters of the SAN simulator comprise any one or more of the following: a maximum read speed, a maximum write speed, an amount of computational power, bandwidth, and latency.

17. The system of claim 13, wherein the processor, upon executing the instructions, is further configured to:
determine a difference between the measured metric and the predicted metric; and
use the difference as at least a part of a cost function for training the MLA.

18. A system for simulating a storage area network (SAN) system, the system comprising:
an iterative SAN simulator for modeling a plurality of components of the SAN system; and
a machine learning algorithm (MLA) trained to adjust parameters of the iterative SAN simulator,
the iterative SAN simulator being configured to:
receive, from an operator of the SAN simulator, a plurality of SAN system operations, and
at each iteration of the iterative SAN simulator:
receive input parameters from the MLA, wherein the input parameters correspond to functions of simulated components of the iterative SAN simulator, and
determine, based on the plurality of SAN system operations and the input parameters, (i) predicted metrics of the plurality of components of the SAN system and (ii) output parameters, and wherein
the MLA is configured to, for each iteration of the iterative SAN simulator:
receive the output parameters and the predicted metrics, and
determine, based on the output parameters and the predicted metrics, the input parameters for a next iteration of the iterative SAN simulator.

19. The system of claim 18, further comprising a failure detection system configured to:
determine, based on the predicted metrics, that a simulated failure has occurred; and
determine, based on the simulated failure, an adjustment for the SAN system.

20. The system of claim 18, wherein the iterative SAN simulator is configured to, at each iteration, simulate processing a portion of the plurality of SAN system operations, and wherein the plurality of SAN system operations comprise at least one of a read operation and a write operation.
